(19) United States
(12) Patent Application Publication
(10) Pub. No.: US 2007/0096827 A1
(43) Pub. Date: May 3, 2007

(54) MULTI CONTROLLED OUTPUT LEVELS CMOS POWER AMPLIFIER (PA)

(76) Inventor: Cuong Q. Nguyen, San Jose, CA (US)

Correspondence Address: SQUIRE, SANDERS & DEMPSEY L.L.P, PATENT DEPARTMENT, ONE MARITIME PLAZA, SUITE 300, SAN FRANCISCO, CA, 94111-3492, US

(21) Appl. No.: 11/555,300

(22) Filed: Nov. 1, 2006

Related U.S. Application Data
(60) Provisional application No. 60/733,336, filed on Nov. 2, 2005.

(51) Int. Cl. H03F 3/68

(52) U.S. Cl. 330/295

(57) ABSTRACT

A power amplifier, comprises a plurality of amplifying transistors; a plurality of cascode transistors coupled to the amplifying transistors; and an antenna coupled to the amplifying transistors via a capacitor. The cascode transistors act as switches controlling the coupling of the amplifying transistors to the antenna.

### PRIORITY REFERENCE TO PRIOR APPLICATIONS

This application claims benefit of and incorporates by reference patent application Ser. No. 60/733,336, entitled “MULTI CONTROLLED OUTPUT LEVELS POWERAMPLIFIER (PA) IN CMOS FOR THE UWB,” filed on Nov. 2, 2005, by inventor Cuong Quoc NGUYEN.

### TECHNICAL FIELD

This invention relates generally to transmitters, and more particularly, but not exclusively, provides a power amplifier for use in a transmitter or other device.

### BACKGROUND

To be competitive in semiconductor business, products must be low cost, smaller in size, have low power consumption and high performance. To achieve these goals, one of the best ways is to design a chip with the in-expensive and mature process such as Complementary Metal-Oxide Semiconductor (CMOS), and integrate all circuits as much as possible to minimize the use of external components.

A power amplifier (PA) is the output stage of a transmitter; it amplifies a signal to required level before transmitting out. In ultra wideband protocol (UWB), it requires very low transmitted power spectrum density over wide bandwidth. However, conventional PAs cannot accommodate different transmitting power levels. As such, a new power amplifier is needed that integrates multi-controlled power levels.

### SUMMARY

A simpler circuit consumes less power; more circuits integrated, lowers the cost and could result in higher performance. In an embodiment of the invention, a PA can be digitally programmed to change the output power level while maintaining the linearity and the bandwidth. This design can help to achieve these above requirements, and it can be also used for any applicable transmitter.

In an embodiment, a power amplifier comprises a plurality of amplifying transistors; a plurality of cascode transistors coupled to the amplifying transistors; and an antenna coupled to the amplifying transistors via a capacitor. The cascode transistors act as switches controlling the coupling of the amplifying transistors to the antenna.

In an embodiment, a method comprises: receiving a voltage with a first capacitor; converting the voltage to a plurality of currents using a plurality of amplifying transistors; and coupling one or more of the plurality of currents to an antenna via a second capacitor using a plurality of cascode transistors.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating a transmitter section in accordance with an embodiment of the present invention;

FIG. 2 is a diagram illustrating a power amplifier of the transmitter section; and

FIG. 3 is a flowchart illustrating a method of amplifying.

### DETAILED DESCRIPTION OF THE ILLUSTRATED EMBODIMENTS

The following description is provided to enable any person having ordinary skill in the art to make and use the invention, and is provided in the context of a particular application and its requirements. Various modifications to the embodiments will be readily apparent to those skilled in the art, and the principles defined herein may be applied to other embodiments and applications without departing from the spirit and scope of the invention. Thus, the present invention is not intended to be limited to the embodiments shown, but is to be accorded the widest scope consistent with the principles, features and teachings disclosed herein.

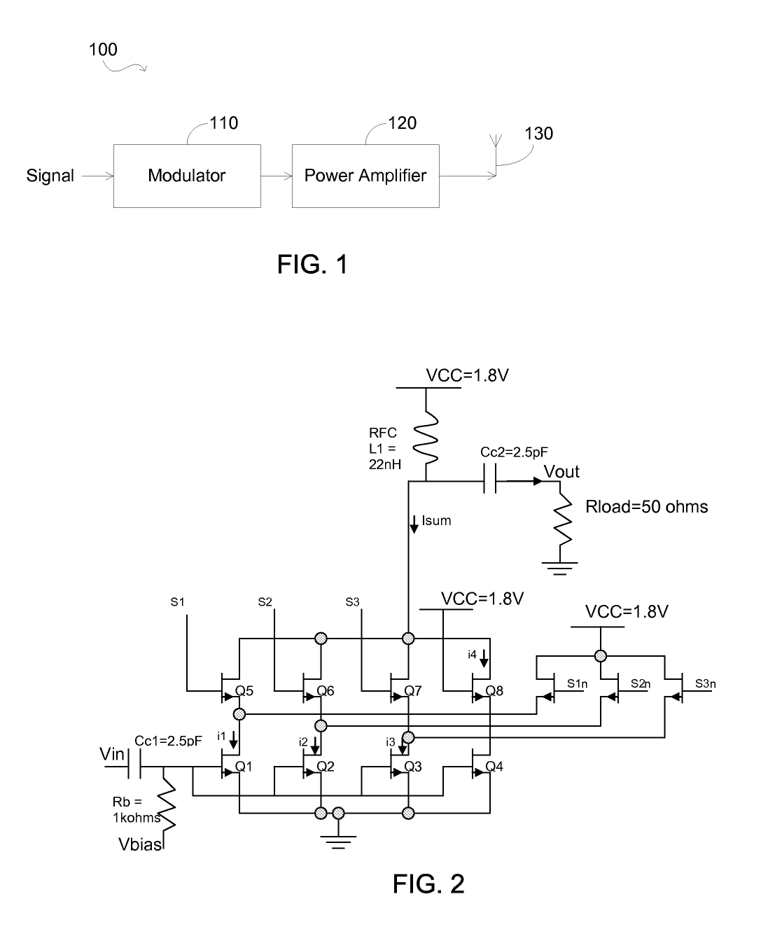

FIG. 1 is a block diagram illustrating a transmitter section 100 in accordance with an embodiment of the present invention. The section 100 includes a modulator 110, communicatively coupled to a power amplifier 120, which is communicatively coupled to an antenna 130. The modulator 110 receives a signal and modulates it with data needed to be communicated. The power amplifier 120 then amplifies the modulated signal. The antenna 130 then broadcasts the amplified modulated signal. In an embodiment of the invention, a transceiver can incorporate the transmitter section 100.

FIG. 2 is a diagram illustrating a power amplifier 120 of the transmitter section 100. In an embodiment, the PA 120 includes 4 amplifying transistors Q1, Q2, Q3, and Q4 coupled to cascode transistors Q5, Q6, Q7 and Q8, respectively. Q5, Q6, and Q7 are controlled by switches S1, S2, and S3, respectively. The current from each transistor Q1, Q2, Q3, and Q4 is coupled to an RLoad via a capacitor Cc2, depending on switch settings.

In an embodiment, the power amplifier 120 includes a 3-controlled output levels cascoding class-A PA. The cascode stage is used for steering current to achieve a desired output level. The cascode NMOS transistors Q5, Q6, Q7, Q8, reduce the Miller effect capacitance, thereby enabling the PA 120 to have a wider bandwidth. It also simplifies the implementation of the control circuitry. The advantage of this technique is the output power level can be digitally controlled, and the settling time will be very fast. In addition, the frequency response of the amplifier 120 will be the same for all levels because the transconductance gm of amplifying NMOS transistors Q1, Q2, Q3, Q4 and the RC loading are the same for all levels.

By setting different size ratio between transistors Q1, Q2, Q3, Q4, the amplifier 120 achieves different controlled levels of attenuation. However, in one embodiment, to simplify the calculation, all transistors are the same size, so their transconductance gₘ is the same.

The Vbias and Rb set the DC bias point of Q1, Q2, Q3 and Q4. The radio frequency choke (RFC) L1 set the DC operating point of the PA output. Rload represents the load of the PA; it is a 50 ohm antenna in one embodiment. S1, S2, S3 and their complement S1n, S2n, S3n are the control signals to program the output power.

During operation, an input signal Vin is AC coupled into the PA 120 through capacitor Cc1. Amplifying transistors Q1, Q2, Q3, and Q4 convert input voltage signal to currents i1, i2, i3, and i4. Q5-Q8 transistors act as the switches, and depend on the setting of S1, S2, S3, the current from each amplifying transistor would be either coupled to Rload through capacitor Cc2 or not. The signal current in each amplifying transistor is calculated as below.
i1=vin*gm1, i2=vin*gm2, i3=vin*gm3, i4=vin*gm4 Equation 1

For all S1, S2, S3 are high, all currents are coupled to output and given the maximum instantaneous power (Pout).
Isum=i1+i2+i3+i4 Equation 2
Pout=(Isum)²*Rload Equation 3
If S1 is low, then the new output power
Isum=i2+i3+i4 Equation 4
Pout=(Isum)²*Rload Equation 5

Likewise, the output power for all other control settings can be calculated.

Using the same concept, the number of controlled levels is expandable to as many as desired, and the output power level resolution for each control bit can be set with the size ratio of amplifying transistors.

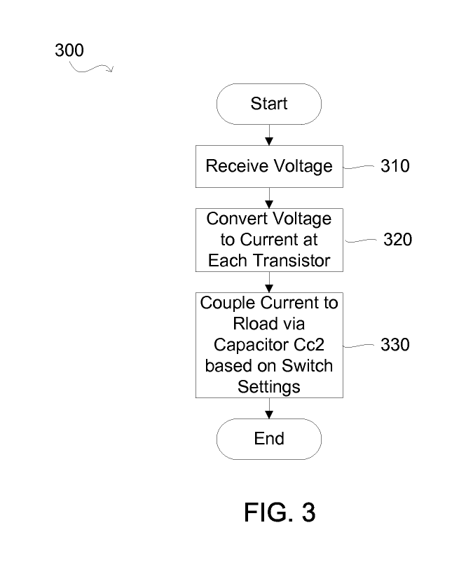

FIG. 3 is a flowchart illustrating a method 300 of amplifying. First, voltage is received (310). The voltage is then converted (320) to currents by a plurality of transistors. The currents are then coupled (330) to RLoad based on switch signals to cascode transistors. The method 300 then ends.

The foregoing description of the illustrated embodiments of the present invention is by way of example only, and other variations and modifications of the above-described embodiments and methods are possible in light of the foregoing teaching. For example, the power amplifier 120 can include few or additional transistors. The embodiments described herein are not intended to be exhaustive or limiting. The present invention is limited only by the following claims.

What is claimed is:

1. A power amplifier, comprising:
a plurality of amplifying transistors;
a plurality of cascode transistors coupled to the amplifying transistors; and
an antenna coupled to the amplifying transistors via a capacitor;
wherein the cascode transistors act as switches controlling the coupling of the amplifying transistors to the antenna.

2. The power amplifier of claim 1, wherein the cascode transistors reduce Miller effect capacitance.

3. The power amplifier of claim 1, wherein the output power level resolution for each cascode transistor control signal is set with the size ratio of the amplifying transistors.

4. The power amplifier of claim 1, wherein the amplifying transistors are all of substantially the same size.

5. A transmitter incorporating the power amplifier of claim 1.

6. A transceiver incorporating the power amplifier of claim 1.

7. A method, comprising:
receiving a voltage with a first capacitor;
converting the voltage to a plurality of currents using a plurality of amplifying transistors; and
coupling one or more of the plurality of currents to an antenna via a second capacitor using a plurality of cascode transistors.

8. The method of claim 7, wherein the cascode transistors reduce Miller effect capacitance.

9. The method of claim 7, wherein the output power level resolution for each cascode transistor control signal is set with the size ratio of the amplifying transistors.

10. The method of claim 7, wherein the amplifying transistors are all of substantially the same size.

11. A power amplifier, comprising:
means for receiving a voltage;
means for converting the voltage to a plurality of currents; and
means for coupling one or more of the plurality of currents to an antenna via a second capacitor.
